(19) United States
(12) Patent Application Publication
(10) Pub. No.: US 2012/0325533 A1
(43) Pub. Date: Dec. 27, 2012

(54) METHOD OF MANUFACTURING MULTILAYER CIRCUIT BOARD AND MULTILAYER CIRCUIT BOARD

(75) Inventor: Hideaki YOSHIMURA, Suzaka (JP)

(73) Assignee: FUJITSU LIMITED, Kawasaki-shi (JP)

(21) Appl. No.: 13/453,211

(22) Filed: Apr. 23, 2012

(30) Foreign Application Priority Data
Jun. 24, 2011 (JP) 2011-141232

(51) Int. Cl. H05K 1/11; B23K 31/02

(52) U.S. Cl. 174/258; 228/165

(57) ABSTRACT

A method of manufacturing a multilayer circuit board includes forming a prepreg on a surface of a first circuit board including a first region in which a plated-through hole is formed and a second region in which a solid pattern is formed, the prepreg having a first hole reaching the plated-through hole and a second hole reaching the solid pattern, filling the first hole with a conductive paste, and pressing a second circuit board on the prepreg to laminate the first circuit board and the second circuit board to each other after filling the first hole with the conductive paste.

### CROSS-REFERENCE TO RELATED APPLICATIONS

This application is based upon and claims the benefit of priority of the prior Japanese Patent Application No. 2011-141232, filed on Jun. 24, 2011, the entire contents of which are incorporated herein by reference.

### FIELD

The embodiment discussed herein is related to a method of manufacturing a multilayer circuit board and a multilayer circuit board.

### BACKGROUND

Recently, in a printed circuit board mounted in a testing apparatus such as a semiconductor tester, an increase of wiring density has been demanded with an increasing number of terminals of a semiconductor device to be tested. Also, in a printed circuit board used in communication equipment and a server, an increase of wiring density has been similarly demanded with an increasing number of terminals of an electronic component to be mounted.

As a technique for increasing the wiring density of the printed wiring board, there is proposed a stacking technique of bonding a plurality of wiring boards, which have been manufactured separately from each other, into one printed circuit board.

In a method of manufacturing a printed wiring board by employing the above-mentioned stacking technique, a prepreg serving as an adhesive layer is first placed between adjacent two of plural wiring boards. Then, the wiring boards are bonded to each other by heating and pressing the prepreg. The prepreg includes through-holes at positions corresponding to lands of the wiring boards, the through-holes being filled with an electroconductive paste. Therefore, when metal particles of the electroconductive (solder) paste filling the through-holes are melted upon the heating and the pressing of the prepreg, the metal particles of the electroconductive (solder) paste are coagulated and the lands of the wiring boards opposed to each other are electrically interconnected. See Japanese Laid-open Patent Publication No. 2000-252595.

A printing method, for example, is often used as a method of supplying the electroconductive paste. In that case, a large amount of liquid resin is added to the electroconductive paste to such an extent as providing a viscosity adapted for the printing method. Accordingly, the metal particles are melted and coagulated upon the heating of the prepreg, disconnection (discontinuity) of the metal may occur between the lands of the wiring boards opposed to each other, thus causing a connection failure between the lands.

The disconnection of the metal can be avoided by, when the wiring boards are bonded together, compressing the electroconductive paste supplied to the through-holes of the prepreg such that the distance between the metal particles is reduced. From the characteristics of the prepreg, however, it is difficult to reduce the spacing between the metal particles by compressing the electroconductive paste. The reason is as follows.

FIG. 10 is a graph depicting the relationship between a remaining copper ratio and a gap between boards when a predetermined load is applied.

In FIG. 10, the remaining copper ratio of a horizontal axis represents a pattern area per unit area. In the case of a solid (full coverage) pattern, for example, the remaining copper ratio is 100%. In the case of a pattern including lines and spaces having equal widths, the remaining copper ratio is 50%. The gap between boards of a vertical axis represents a distance between the wiring boards opposed to each other.

As illustrated in FIG. 10, the gap between boards (i.e., the distance between the wiring boards) depends on the remaining copper ratio (i.e., the pattern density). Therefore, when there are a region where the solid pattern, e.g., a power source pattern or a ground pattern, is arranged and a region where a non-solid pattern, e.g., a land pattern or a wiring pattern, is arranged, it is difficult to make even the distance between the wiring boards.

For example, the distance between the wiring boards is larger in the region where the solid pattern is arranged than in the region where the non-solid pattern is arranged. Accordingly, the prepreg is not sufficiently pressed in some cases in the region where the non-solid pattern is arranged.

As described above, because the electroconductive paste supplied to the through-hole of the prepreg is not sufficiently compressed with the current method of manufacturing the printed wiring board, the connection failure between the lands is not completely avoided.

The technique disclosed herein provides a method of manufacturing a multilayer circuit board by bonding a plurality of wiring boards with a prepreg interposed between adjacent wiring boards, the method increasing reliability of connection between lands of the circuit boards.

### SUMMARY

According to an aspect of the invention, a method of manufacturing a multilayer circuit board includes forming a prepreg on a surface of a first circuit board including a first region in which a plated-through hole is formed and a second region in which a solid pattern is formed, the prepreg having a first hole reaching the plated-through hole and a second hole reaching the solid pattern, filling the first hole with a conductive paste, and pressing a second circuit board on the prepreg to laminate the first circuit board and the second circuit board to each other after filling the first hole with the conductive paste.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a sectional view of a multilayer circuit board according to one embodiment;

FIG. 2 is a plan view of a first circuit board according to the one embodiment;

FIGS. 3A and 3B are sectional views of a land connecting portion and a glass cut portion according to the one embodiment;

FIGS. 4A and 4B are explanatory views to explain manufacturing steps of the multilayer circuit board according to the one embodiment;

FIGS. 5A and 5B are explanatory views to explain manufacturing steps of the multilayer circuit board according to the one embodiment;

FIG. 6 is an explanatory view to explain a manufacturing step of the multilayer circuit board according to the one embodiment;

FIG. 7 is an explanatory view to explain a manufacturing step of the multilayer circuit board according to the one embodiment;

FIGS. 8A and 8B are explanatory views to explain change of the glass cut portion in the one embodiment;

FIGS. 9A, 9B and 9C are explanatory views to explain change of the land connecting portion in the one embodiment; and

FIG. 10 is a graph depicting the relationship between a remaining copper ratio and a gap between boards.

### DESCRIPTION OF EMBODIMENT

[Multilayer Circuit Board]

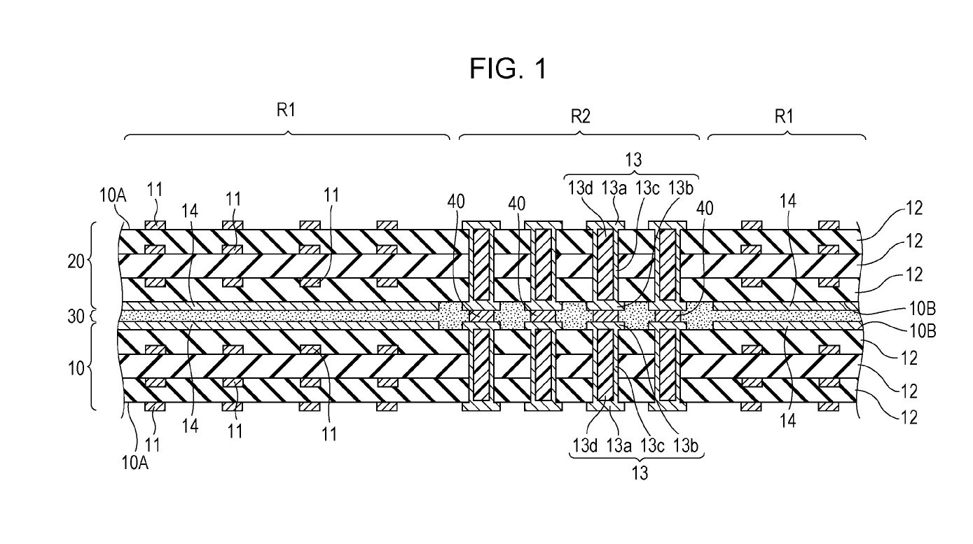

The construction of a multilayer circuit board will be described below with reference to FIGS. 1, 2, 3A and 3B.

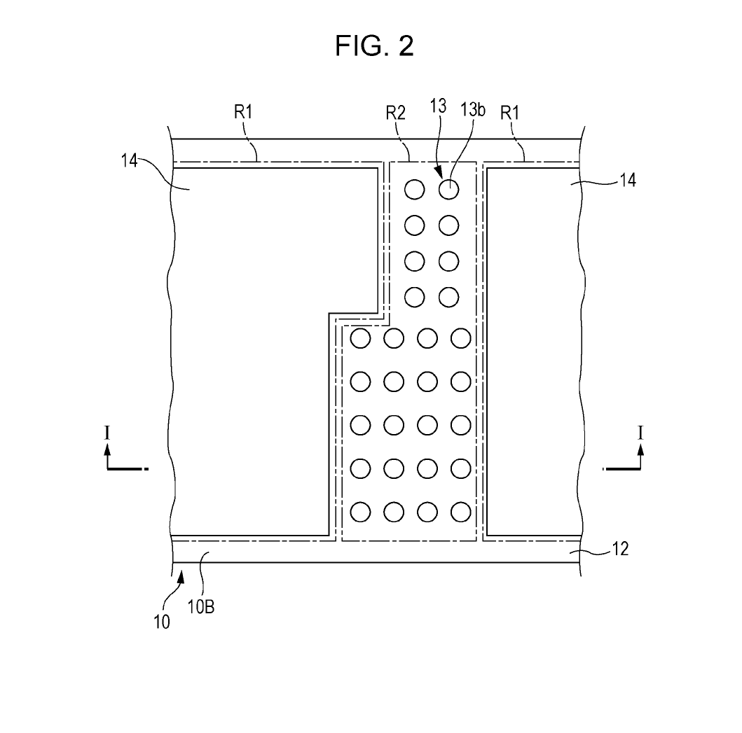

FIG. 1 is a sectional view of a multilayer circuit board according to one embodiment. FIG. 2 is a plan view of a first circuit board 10 according to the one embodiment, and it depicts a second surface 10B of the first circuit board 10 in FIG. 1, to which surface an intermediate insulating layer 30 is bonded. It is to be noted that FIG. 1 depicts a cross-section taken along a line I-I in FIG. 2.

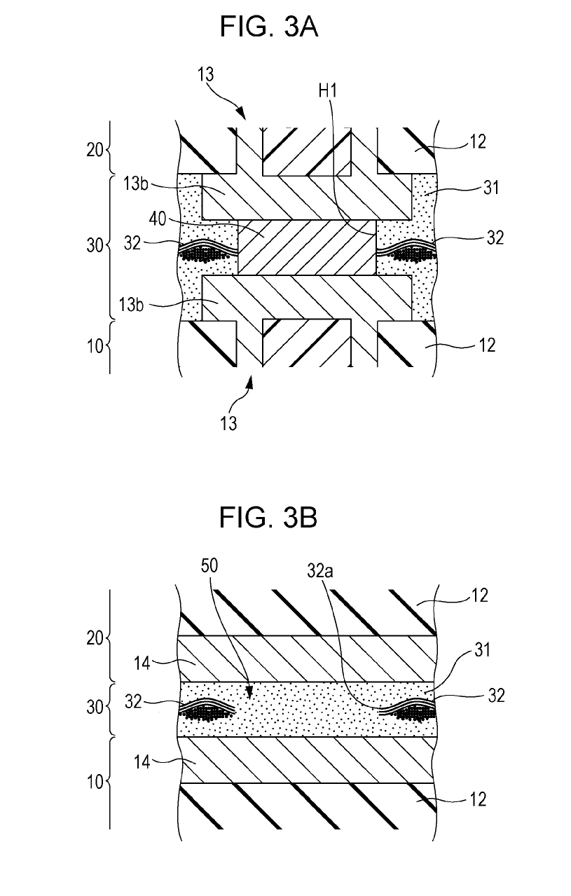

As illustrated in FIGS. 1 and 2, the multilayer circuit board includes the first circuit board 10, a second circuit board 20, the intermediate insulating layer 30 for joining the first and second circuit boards 10 and 20 to each other, a land connecting portion 40 for electrically connecting respective second lands 13b of the first and second circuit boards 10 and 20 to each other, and a glass cut portion 50 (see FIG. 3B). Since the first and second circuit boards 10 and 20 have basically the same construction, the following description is made only about the first circuit board 10.

The first circuit board 10 is the so-called multilayer wiring board formed by alternately stacking a wiring layer 11 and an insulating layer 12. While, in this embodiment, the first circuit board 10 includes three wiring layers 11 and three insulating layers 12, the number of stacked layers is not limited to such an example. Materials of the insulating layer 12 are not limited to particular one. For example, a material obtained by impregnating a glass cloth with an FR4 (Flame Retardant Type 4) based liquid resin, to which a silica filler is added, is used in this embodiment. The glass cloth is provided, for example, as a cloth according to the IPC (Institute For Interconnecting and Packaging Electronics Circuits) standard #1078.

The first circuit board 10 includes a plurality of plating through-holes 13. The plating through-holes 13 are each formed to penetrate through the three insulating layers 12 and to reach a first surface 10A and a second surface 10B of the first circuit board 10.

The plating through hole 13 includes a first land 13a formed on the first surface 10A, a second land 13b formed on the second surface 10B, a via hole 13c penetrating through the three insulating layers 12 and electrically connecting the first and second lands 13a and 13b to each other, and a resin portion 13d filling the via hole 13c.

The first land 13a is an electrode of the multilayer circuit board for connection to the outside and is connected to a terminal of an electronic component of a semiconductor device, for example. The second land 13b is electrically connected to a second land 13b of the second circuit board 20 through a land connecting portion 40 (described later). The first and second lands 13a and 13b are each formed in a circular shape when viewed from above. In this embodiment, the thickness of each of the first and second lands 13a and 13b is equal to the thickness of the wiring layer 11 and is set to about 40 μm to 80 μm.

The first land 13a, the second land 13b, and the via hole 13c are continuously formed by, e.g., plating. Materials of the first land 13a, the second land 13b, and the via hole 13c are not limited to particular one. For example, a metal material, such as Cu, is used in this embodiment.

The via hole 13c is formed by an inner surface of a bore penetrating through the three insulating layers 12. The resin portion 13d reaches both the first and second lands 13a and 13b. Materials of the resin portion 13 are not limited to particular one. For example, an epoxy resin may be used.

Further, a solid (full coverage) pattern 14 is arranged on the second surface 1013 of the first circuit board 10. The solid pattern 14 is a general term of, e.g., a power source pattern, a ground pattern, a dummy pattern, and so on. The solid pattern 14 has a larger area than that of at least the first and second lands 13a and 13b. In this embodiment, the thickness of the solid pattern 14 is equal to the thickness of the second land 13b and is set to about 40 μm to 80 μm.

In the following description, a region in the first circuit board 10 where the solid pattern 14 is arranged is called a first region R1, and a region in the first circuit board 10 where the second land 13b is arranged is called a second region R2.

The intermediate insulating layer 30 includes a resin member 31 and a glass cloth 32 embedded in the resin member 31. Materials of the resin member 31 are not limited to particular ones insofar as the material is a thermosetting resin having low fluidity. The same resin as that used for the insulating layer 12, i.e., the material obtained by impregnating the glass cloth with the FR4 based liquid resin to which the silica filler (not illustrated) is added, is used in this embodiment. The glass cloth 32 is formed by weaving a plurality of glass fibers into a cloth. The thickness of the glass cloth 32 is not limited to particular one, but it is set to about 45 μm, for example, in this embodiment.

The thickness of the intermediate insulating layer 30 in the first region R1 is uniform in the planar direction of the first and second circuit boards 10 and 20, i.e., in the direction parallel to the second surface 10B. The thickness of the intermediate insulating layer 30 in the second region R2 differs between a position where the second land 13b is formed and a position where the second land 13b is not formed. In other words, the thickness of the intermediate insulating layer 30 at the position where the second land 13b is formed is smaller by a value twice the thickness of the second land 13b than that of the intermediate insulating layer 30 at the position where the second land 13b is not formed. It is, however, to be noted that the density (g/mm³) of the intermediate insulating layer 30 is uniform in the planar direction of the first and second circuit boards 10 and 20 throughout the first and second regions R1 and R2.

FIGS. 3A and 3B are sectional views of the land connecting portion 40 and the glass cut portion 50 according to the one embodiment.

As illustrated in FIG. 3A, the land connecting portion 40 mechanically and electrically connects the second land 13b of the first circuit board 10 and the second land 13b of the second circuit board 20 to each other. The land connecting portion 40 is formed in a columnar shape in close contact with an inner surface of a connection hole H1 (described later) that is formed in the intermediate insulating layer 30. The land connecting portion 40 has a smaller diameter than that of the second land 13b, and it is joined to a central surface portion of the second land 13b. Materials of the land connecting portion 40 are not limited to particular one. For example, a low-melting metal, e.g., a solder, is used in this embodiment. Materials of the solder are not limited to particular one. For example, an alloy of tin, bismuth, and copper is used in this embodiment.

As illustrated in FIG. 3B, the glass cut portion 50 is a portion where the resin member 31 of the intermediate insulating layer 30 fills a cutout 32a formed in the glass cloth 32 of the intermediate insulating layer 30. The cutout 32a has an inner diameter larger than at least the gap size among the glass fibers, i.e., the mesh size of the glass cloth 32. It is to be noted that the glass cut portion 50 corresponds to a portion in which an adjustment hole H2 (described later) is formed.

Thus, the first and second circuit boards 10 and 20 constitute one multilayer circuit board with the respective second lands 13b of the first and second circuit boards 10 and 20 mechanically and electrically connected to each other through the land connecting portions 40.

[Manufacturing Steps of Multilayer Circuit Board]

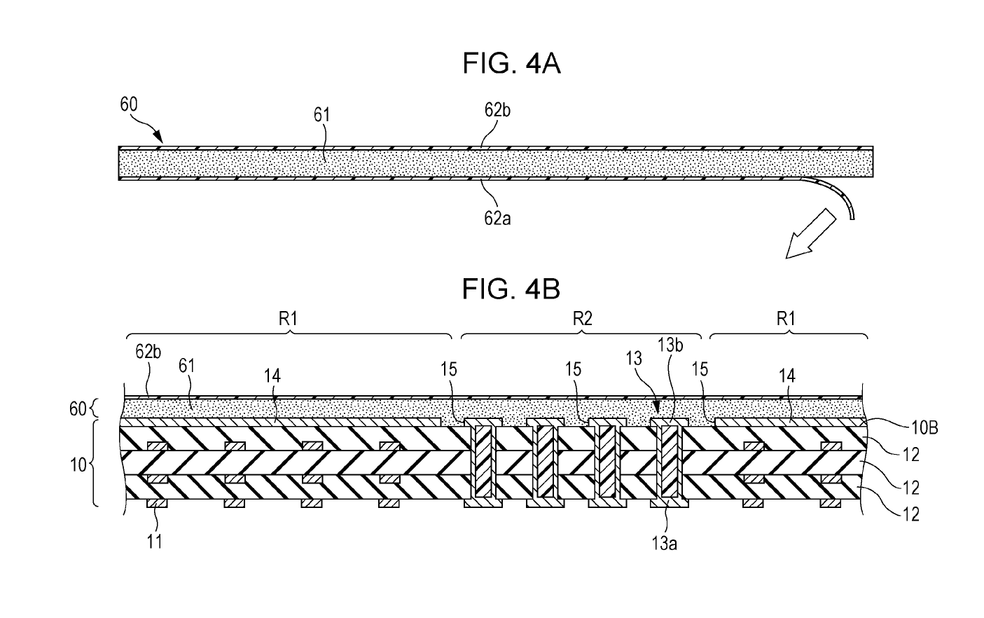

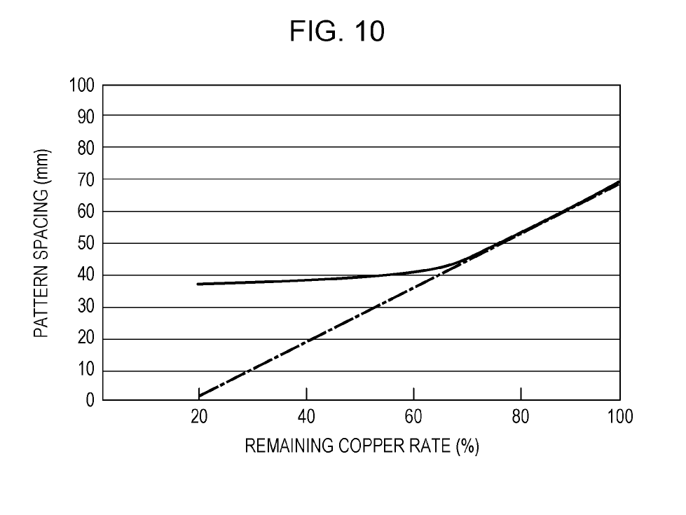

The manufacturing steps of the multilayer circuit board will be described below with reference to FIGS. 4A to 10.

FIGS. 4A to 7B are explanatory views to explain the manufacturing steps of the multilayer circuit board according to the one embodiment.

As illustrated in FIG. 4A, an adhesive sheet 60 is prepared. The adhesive sheet 60 includes a prepreg 61 in the form of a sheet, and first and second films 62a and 62b pasted respectively to both surfaces of the prepreg 61. The first film 62a of the adhesive sheet 60 is then peeled off, as indicated by an arrow, whereby the prepreg 61 is exposed.

The prepreg 61 becomes the intermediate insulating layer 30 of the multilayer circuit board. Materials of the prepreg 61 are not limited to particular one. The same resin as that used for the insulating layer 12, i.e., the material obtained by impregnating a glass cloth 63 according to the IPC standard #1078 with the FR4 based liquid resin to which the silica filler is added, is used in this embodiment. The glass cloth 63 becomes the glass cloth 32 of the multilayer circuit board.

The thickness of the prepreg 61 is not limited to particular one, but it is set to about 85 μm, for example, in this embodiment. The thickness of the glass cloth 63 is not limited to particular one, but it is set to about 45 μm, for example, in this embodiment.

The adhesive sheet 60 may have a hole through which a positioning mark (not illustrated) formed on the first circuit board 10 is to be exposed. A method of forming the hole through which the positioning mark is to be exposed is not limited to particular one. That hole may be formed by, e.g., drilling.

The first and second films 62a and 62b function not only as protective films for protecting the prepreg 61, but also as stencil sheets (described later) for printing. Materials of the first and second films 62a and 62b are not limited to particular one. For example, PET (Polyethylene Terephthalate) is used in this embodiment. The thickness of each of the first and second films 62a and 62b is not limited to particular one, but it is set to about 38 μm, for example, in this embodiment.

Next, as illustrated in FIG. 4B, the adhesive sheet 60 from which the first film 62a has been peeled off is placed on the second surface 10B of the first circuit board 10 in such a state that the prepreg 61 is contacted with the second surface 10B.

Then, the first circuit board 10 and the adhesive sheet 60 are carried into a press-bonding chamber, and the press-bonding chamber is depressurized. When the inside of the press-bonding chamber reaches a predetermined degree of vacuum, the adhesive sheet 60 is press-bonded to the second surface 10B of the first circuit board 10 under heating and pressing.

At that time, the liquid resin of the prepreg 61 is caused to flow into gaps 15 between the adjacent second lands 13b. Therefore, the thickness of the prepreg 61 in the second region R2 is reduced in some degree corresponding to a volume of the liquid resin that has flowed into the gaps 15. As a result, the thickness of the prepreg 61 in the second region R2 becomes smaller than that of the prepreg 61 in the first region R1. The surface of the prepreg 61 may become wavy depending on the shape of the second land 13b. Bonding conditions are not limited to particular ones. For example, a pressure of 0.5 MPa, a temperature of 100° C., and a pressing time of 180 sec are set as the bonding conditions.

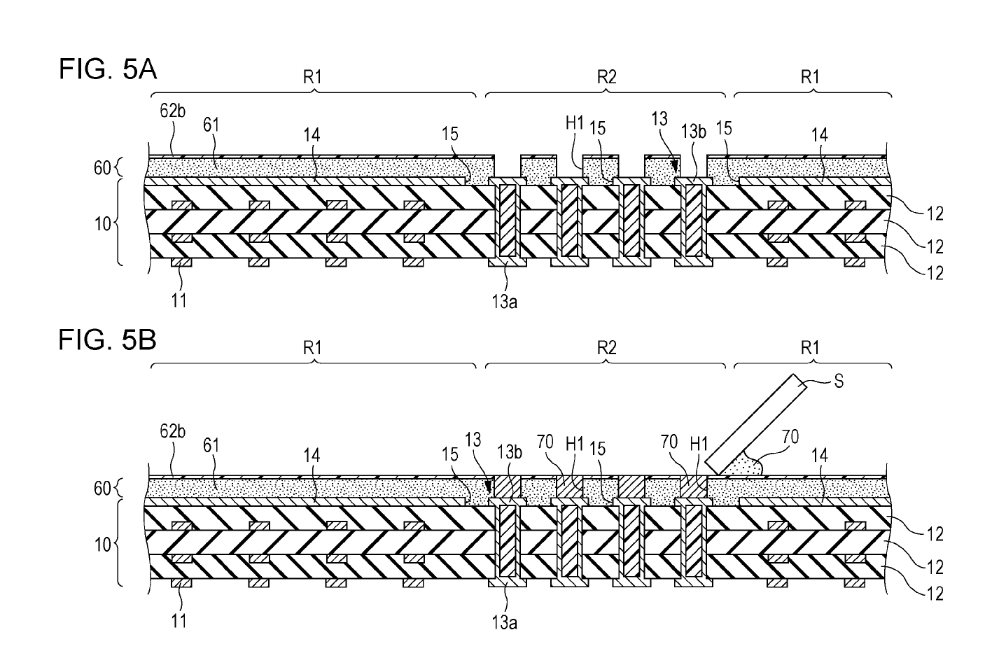

Next, as illustrated in FIG. 5A, plural connection holes H1 are formed in the adhesive sheet 60 in the second region R2. The connection holes H1 are formed to reach the corresponding second lands 13b such that the second lands 13b are exposed through the connection holes H1, respectively. The shape of the connection hole H1 is not limited to particular one. In this embodiment, the shape of the connection hole H1 is, for example, circular when viewed from above. The diameter of the connection hole H1 is not limited to particular one insofar as it is smaller than the diameter of the second land 13b.

A method of forming the connection hole H1 is not limited to particular one. Trepanning with laser machining is used in this embodiment. For example, a carbon dioxide gas laser may be used as a laser. As laser machining conditions, the spot diameter of a laser beam is set to φ200 μm, and the laser output is set to 4 mJ.

In the laser machining, the positioning mark (not illustrated) formed on the first circuit board 10 may be used to determine an irradiation position of the laser beam. Further, when a smear occurs in the connection hole H1, the smear may be removed, for example, by making the smear exposed to plasma.

Next, as illustrated in FIG. 5B, a solder paste 70 fills each of the connection holes H1. For example, a printing process may be used as a method of applying the solder paste 70. In this embodiment, the connection hole H1 is filled with the solder paste 70 by using a squeegee S with the second film 62b on the adhesive sheet 60 serving as a stencil sheet. When an amount of the solder paste 70 supplied is to be increased, a metal mask may be additionally used. As another example, a dispensing process may be used instead of the printing process.

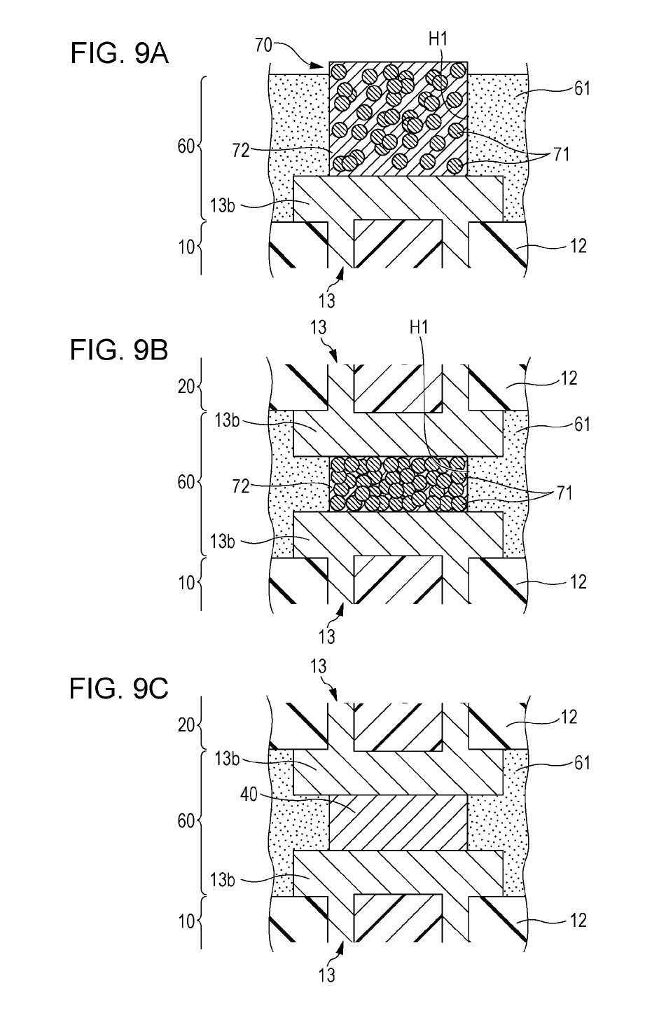

As illustrated in FIG. 9A, the solder paste 70 is in a paste-like state obtained by kneading many solder particles 71 and a liquid resin 72. The solder particles 71 and the liquid resin 72 are mixed with each other at a volume ratio of about 1:1. The viscosity of the solder paste 70 is not limited to particular one. In this embodiment, the viscosity of the solder paste 70 is set to a value demanded in the printing process, i.e., about 200 Pa·S, through optimization of the liquid resin 72.

Materials of the solder particles 71 are not limited to particular one. For example, a low-melting metal containing tin, bismuth, and copper is used in this embodiment. Materials of the liquid resin 72 are not limited to particular one. The same liquid resin as that used in the prepreg 61 may be used.

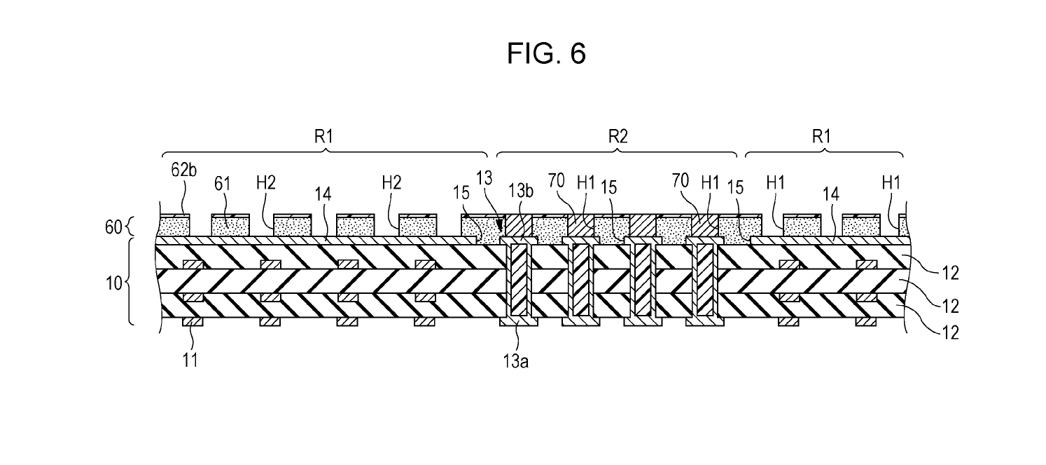

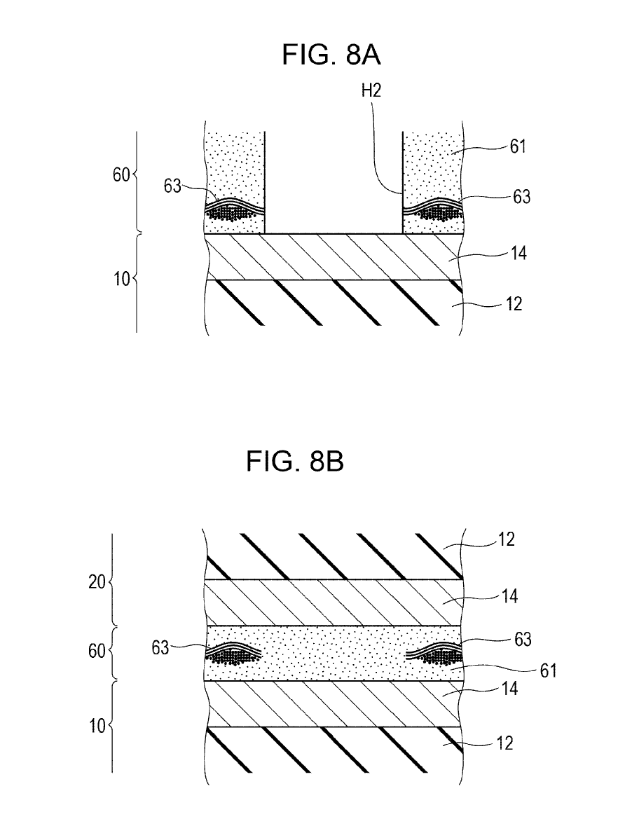

Next, as illustrated in FIG. 6, plural adjustment holes H2 are formed in the adhesive sheet 60 in the first region R1. The adjustment holes H2 are arranged at a uniform density over the entire first region R1. The adjustment holes H2 are formed to reach the solid pattern 14 such that the solid pattern 14 is exposed through the adjustment holes H2. Further, as illustrated in FIG. 8A, the glass cloth 63 of the adhesive sheet 60 is exposed at an inner surface of each of the adjustment holes H2. The shape of the adjustment hole H2 is not limited to particular one. In this embodiment, the shape of the adjustment hole H2 is, for example, circular when viewed from above. The number and the size of the adjustment holes H2 are calculated depending on the area, the number, and the density of the second lands 13b of the first circuit board 10. In this embodiment, the diameter of the adjustment hole H2 is set to 700 μm on the surface side of the adhesive sheet 60 and to 600 μm on the backside of the adhesive sheet 60 closer to the first circuit board 10.

A method of forming the adjustment hole H2 is not limited to particular one. Trepanning with laser machining is used in this embodiment. For example, a carbon dioxide gas laser may be used as a laser. As laser machining conditions, the spot diameter of a laser beam is set to φ200 μm, and the laser output is set to 4 mJ.

In the laser machining, the positioning mark (not illustrated) formed on the first circuit board 10 may be used to determine an irradiation position of the laser beam. Further, when a smear occurs in the adjustment hole H2, the smear may be removed, for example, by making the smear exposed to plasma.

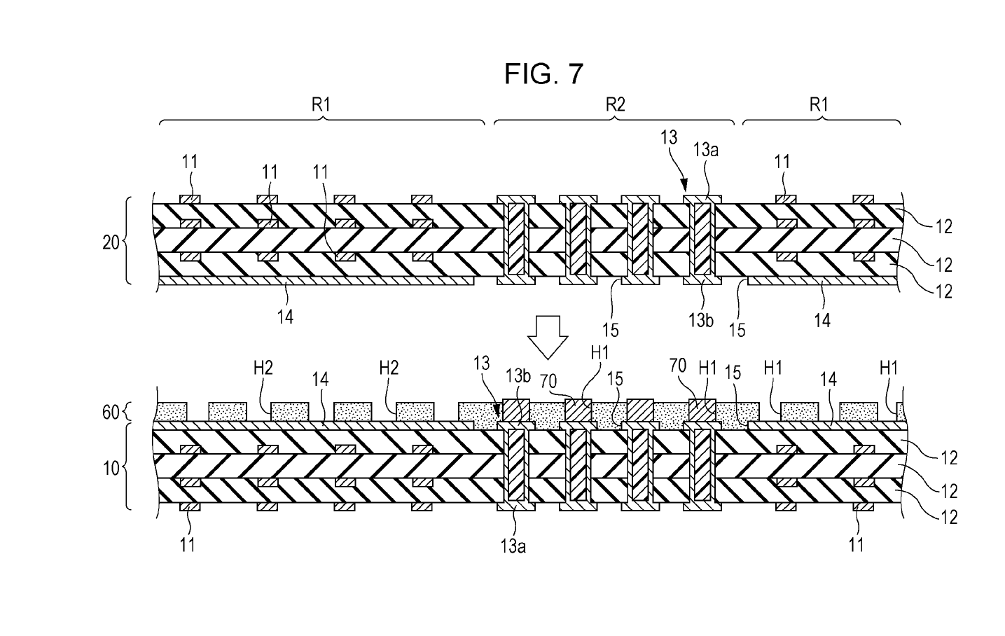

Next, as illustrated in FIG. 7, the second film 62b on the adhesive sheet 60 is peeled off such that the prepreg 61 is exposed. With the peeling-off of the second film 62b, the solder paste 70 filling the connection holes H1 after the printing comes into a state projecting from the surface of the prepreg 61 in some degree corresponding to the thickness of the second film 62b.

The second circuit board 20 having the same construction as the first circuit board 10 is then placed on the prepreg 61 of the adhesive sheet 60 such that the second surface 10B is contacted with the prepreg 61. Thereafter, the first and second circuit boards 10 and 20 and the prepreg 61 are carried into the press-bonding chamber, and the press-bonding chamber is depressurized. When the inside of the press-bonding chamber reaches a predetermined degree of vacuum, the second circuit board 20 is press-bonded to the prepreg 61 under heating and pressing. As a result, the first and second circuit boards 10 and 20 are joined to each other.

At that time, the prepreg 61 in the first region R1 is pressed through the first and second circuit boards 10 and 20, thus causing the liquid resin of the prepreg 61 to flow into the adjustment holes H2. Therefore, the adjustment holes H2 are filled with the liquid resin flowing in from the prepreg 61 as illustrated in FIG. 8B, whereby the thickness of the prepreg 61 in the first region R1 is reduced in some degree corresponding to a volume of the adjustment holes H2. The size and the density of the adjustment holes H2 are determined such that the volume of the adjustment holes H2 per unit area of the first region R1 is equal to the volume of the gaps 15 per unit area of the second region R2. Accordingly, the thickness of the prepreg 61 in the first region R1 becomes equal to that of the prepreg 61 in the second region R2. Hence, the prepreg 61 in the second region R2 is pressed under the same pressure as that pressing the prepreg 61 in the first region R1.

When the prepreg 61 in the second region R2 is pressed, the liquid resin 72 in the solder paste 70 is caused to diffuse into the prepreg 61 from the inner surfaces of the connection holes H1. However, diffusion of the solder particles 71 in the solder paste 70 is impeded by the silica filler added to the prepreg 61, and the solder particles 71 remain in the connection holes H1.

In other words, as illustrated in FIG. 9B, the density (number/mm³) of the solder particles 71 in each of the connection holes H1 is increased and the spacing between the solder particles 71 is reduced. Accordingly, when the solder particles 71 are melted under the heating and the pressing of the first and second circuit boards 10 and 20, a larger number of solder particles 71 are coagulated to form the land connecting portion 40 that continuously extends from the second land 13b of the first circuit board 10 to the second land 13b of the second circuit board 20 without including disconnection, as illustrated in FIG. 9C. As a result, the second land 13b of the first circuit board 10 and the second land 13b of the second circuit board 20 are mechanically and electrically connected to each other by the land connecting portions 40. The multilayer circuit board is thus completed.

Conditions for press-bonding the first and second circuit boards 10 and 20 are not limited to particular ones. A pressure of 3 to 5 MPa, a heating temperature of 180° C. to 200° C., and a pressing time of 2 to 3 hours are set as the press-bonding conditions in this embodiment. The heating temperature may be raised at a pace of, e.g., 3° C./minute.

### Example

Changes in land-to-land spacing between before and after joining first and second circuit boards to each other are compared below when a first prepreg S1 including adjustment holes and a second prepreg S2 not including the adjustment holes are used. In this EXAMPLE, after laminating the first prepreg 51 or the second prepreg S2 on the surface of the first circuit board, the second circuit board is jointed to the first circuit board with the first prepreg 51 or the second prepreg S2 interposed between them.

It is supposed that the planar dimensions of each of the first and second prepregs 51 and S2 are 510 mm×610 mm, and the thickness of each of the first and second prepregs 51 and S2 immediately after laminating the first circuit board is 110 μm. Further, the diameter of the adjustment holes formed in the first prepreg 51 is φ600 μm to φ700 μm, and the number of the adjustment holes is 100,000. The pressure applied at the time of joining the first and second circuit boards to each other is 3 MPa.

As a result of conducting experiments under the above-described conditions, the land-to-land spacing (or the thickness of the prepreg) in the case using the first prepreg 51 was about 60 μm, and the land-to-land spacing (or the thickness of the prepreg) in the case using the second prepreg S2 was about 70 μm. It was thus proved that the land-to-land spacing was reduced by forming the plural adjustment holes in the prepreg.

With the embodiment described above, the plural adjustment holes H2 are formed in the prepreg 61 in the first region R1 where the solid pattern 14 is arranged. Therefore, when the prepreg 61 in the first region R1 is pressed, the liquid resin of the prepreg 61 is caused to flow into the adjustment holes H2, and the thickness of the prepreg 61 is reduced correspondingly.

Consequently, the thickness of the prepreg 61 in the first region R1 can be made equal to that of the prepreg 61 in the second region R2. Hence, the prepreg 61 in the second region R2 can also be sufficiently pressed, and the solder paste 70 filling in the connection holes H1 can be compressed.

More specifically, the liquid resin 72 of the solder paste 70 filling in the connection holes H1 is caused to diffuse into the prepreg 61, and the density (number/mm³) of the solder particles 71 in the connection holes H1 is increased. Therefore, when the solder particles 71 are melted, they are more apt to coagulate into one metal mass (i.e., the land connecting portion 40). In other words, it is possible to inhibit a coagulation failure that may be caused when the spacing between the solder particles 71 is large. Thus, reliability in connection between the second land 13b of the first circuit board 10 to the second land 13b of the second circuit board 20 can be increased. Further, since the cross-section of each of the land connecting portions 40 is enlarged, an allowable current flowing through the land connecting portion 40 can be increased.

Moreover, since the solid pattern 14 serves as a machining stop film, the first circuit board 10 can be kept from being damaged even when laser machining is used as the method of forming the adjustment holes H2.

In addition, with the embodiment described above, the connection holes H1 and the adjustment holes H2 are formed in the adhesive sheet 60 after bonding the adhesive sheet 60 to the first circuit board 10. Therefore, the positions of the connection holes H1 and the adjustment holes H2 are not deviated even if the shape of the adhesive sheet 60 is changed when the adhesive sheet 60 is bonded to the first circuit board 10.

In the embodiment described above, the connection holes H1 and the adjustment holes H2 are formed in the adhesive sheet 60 having been bonded to the first circuit board 10. However, the adhesive sheet 60 may be sandwiched between baked plates, and after forming the connection holes H1 and the adjustment holes H2 in the adhesive sheet 60 as well as in the baked plates, the adhesive sheet 60, including the baked plates, may be bonded to the first circuit board 10. When the connection holes H1 and the adjustment holes H2 are formed by drilling, plural adhesive sheets 60 may be placed one on another, and the connection holes H1 and the adjustment holes H2 may be formed through the plural adhesive sheets 60 at the same time.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A method of manufacturing a multilayer circuit board, the method comprising:
forming a prepreg on a surface of a first circuit board including a first region in which a plated-through hole is formed and a second region in which a solid pattern is formed, the prepreg having a first hole reaching the plated-through hole and a second hole reaching the solid pattern;
filling the first hole with a conductive paste; and
pressing a second circuit board on the prepreg to laminate the first circuit board and the second circuit board to each other after filling the first hole with the conductive paste.

2. The method of manufacturing the multilayer circuit board according to claim 1,
wherein the forming the prepreg comprises:
bonding a prepreg material to the surface of the first circuit board;
forming the first hole in the prepreg material after bonding the prepreg material; and
forming the second hole in the prepreg material after filling the first hole with the conductive paste.

3. The method of manufacturing the multilayer circuit board according to claim 1,
wherein the forming the prepreg comprises:
bonding a prepreg material to the surface of the first circuit board; and
forming the first hole and the second hole in the prepreg material after bonding the prepreg material.

4. The method of manufacturing the multilayer circuit board according to claim 1,
wherein the prepreg includes an insulating fiber cloth reaching an inner surface of the second hole.

5. The method of manufacturing the multilayer circuit board according to claim 2,
wherein the prepreg includes:
a resin material; and
an insulating fiber cloth in the resin material, and
wherein the forming the second hole cuts the insulating fiber cloth.

6. The method of manufacturing the multilayer circuit board according to claim 1,
wherein the plated-through hole includes a pattern portion projecting from the surface of the first circuit board, the pattern portion being smaller than the solid pattern.

7. A multilayer circuit board comprising:
a first circuit board including a first region in which a plated-through hole is formed and a second region in which a solid pattern is formed;
an insulating layer provided on the first circuit board and having a hole reaching the plated-through hole;
a second circuit board provided on the insulating layer; and
a conductive member provided in the hole and electrically connecting the first circuit board and the second circuit board to each other,
wherein the insulating layer includes
a resin material, and
an insulating fiber cloth in the resin material, the insulating fiber cloth having a hole larger than a mesh of the insulating fiber cloth at a position corresponding to the solid pattern.
